(19) United States
(12) Patent Application Publication
(10) Pub. No.: US 2022/0190261 A1
(43) Pub. Date: Jun. 16, 2022

(54) LIGHT EMITTING DEVICE

(71) Applicant: SHARP KABUSHIKI KAISHA, Sakai City, Osaka (JP)

(72) Inventor: Yukio TAKENAKA, Sakai City, Osaka (JP)

(21) Appl. No.: 17/441,067

(22) PCT Filed: Mar. 22, 2019
(86) PCT No.: PCT/JP2019/012251

§ 371 Date: Sep. 20, 2021

(51) Int. Cl. H01L 51/00

(52) U.S. Cl. CPC H01L 51/0094; H01L 51/502

(57) ABSTRACT

Provided is a light-emitting element including a first electrode, a second electrode, and a light-emitting layer provided between the first electrode and the second electrode. The light-emitting layer includes quantum dots and a first polysilsesquioxane having electrical conductivity.

### TECHNICAL FIELD

The present invention relates to a light-emitting element.

### BACKGROUND ART

In recent years, various display devices have been developed. In particular, a display device provided with a quantum dot light-emitting diode (QLED) has attracted a great deal of attention from perspectives such as the ability to achieve lower power consumption, a slimmer design, and higher picture quality.

In the field of QLED, it is known that organic ligands on the surface of quantum dots (QD) are responsible for reducing durability, and thus there is a need for chemically and thermally stable materials that can seal quantum dots.

FIG. 17 is an illustration of a conventional nanoparticle and a conventional film in which quantum dots are sealed with a chemically and thermally stable material. (a) of FIG. 17 illustrates a schematic configuration of a nanoparticle 100 disclosed in NPL 1 and NPL 2, and (a) of FIG. 17 illustrates a silica layer 103 included in the nanoparticle 100. As illustrated in (a) of FIG. 17, the nanoparticle 100 includes a quantum dot 101, a siloxane monomolecular film 102 coordinated on the surface of the quantum dot 101, and the silica layer 103 formed so as to cover the siloxane monomolecular film 102. (c) of FIG. 17 illustrates a schematic configuration of a film 110 containing quantum dots 111 as disclosed in PTL 1, the film 110 including the quantum dots 111 and a silica layer 112 formed using a trialkoxy silane coordinated on the surface of each quantum dot 111. (d) of FIG. 17 illustrates a schematic configuration of a nanoparticle 120 disclosed in PTL 2, where the nanoparticle 120 includes a quantum dot 121 made from Si and constituting the core and a silica layer 122 forming a shell.

As described above, in the conventional nanoparticle and conventional film illustrated in FIG. 17, the quantum dots are sealed with silica, which is a chemically and thermally stable material, and thus the durability of the quantum dots can be improved.

### CITATION LIST

### Non Patent Literature

NPL 1: ACS Nano 2013, 7, 2, 1472

NPL 2: Nanotechnology 2017, 28, 185603

### PATENT LITERATURE

PTL 1: US 2004/0,266,148 A1 (published 30 Dec. 2004)

PTL 2: JP 2006-237595 A (published 7 Sep. 2006)

### SUMMARY OF INVENTION

### Technical Problem

However, with each of the inventions disclosed in NPL 1, NPL 2, PTL 1, and PTL 2, silica is used as the material for sealing the quantum dots. Such silica-sealed quantum dots can be excited by light and caused to emit light, but the silica is an insulator with a large band gap, and therefore results in a problem of requiring a very large voltage to inject electrons and positive holes and emit light.

In light of the foregoing, an object of the present invention is to provide a light-emitting element that is highly durable and can emit light through the injection of electrons and positive holes at a relatively low voltage.

### Solution to Problem

In order to solve the problem described above, a light-emitting element of the present invention includes a first electrode, a second electrode, and a light-emitting layer provided between the first electrode and the second electrode, and

the light-emitting layer includes quantum dots and a first polysilsesquioxane having electrical conductivity.

According to the abovementioned light-emitting element, a light-emitting element can be realized that is highly durable and can emit light through the injection of electrons and positive holes at a relatively low voltage.

### Advantageous Effects of Invention

According to one aspect of the present invention, a light-emitting element that is highly durable and can emit light through the injection of electrons and positive holes at a relatively low voltage can be provided.

### BRIEF DESCRIPTION OF DRAWINGS

FIG. 1(a) is a diagram illustrating a schematic configuration of a nanoparticle included in a light-emitting layer of a light-emitting element of a first embodiment. FIG. 1(b) is a diagram illustrating a functional group moiety that coordinates with a quantum dot of a first polysilsesquioxane having electrical conductivity, and FIG. 1(c) is a diagram illustrating a schematic configuration of the first polysilsesquioxane having electrical conductivity.

FIG. 2(a) is a diagram explaining a method for synthesizing silica, FIG. 2(b) is a diagram explaining a method for synthesizing a second polysilsesquioxane having a functional group that coordinates with a quantum dot, and FIG. 2(c) is a diagram explaining a method for synthesizing a first polysilsesquioxane having electrical conductivity.

FIG. 3(a) is a diagram illustrating an example of a silane including a functional group that coordinates with a quantum dot and has an amino group. FIG. 3(b) is a diagram illustrating an example of a silane including a functional group that coordinates with a quantum dot and has a thiol group.

FIGS. 4(a), (b), and (c) are diagrams illustrating examples of ligands that coordinate with quantum dots.

FIGS. 5(a), (b), (c), (d), (e), (f), (g), and (h) are diagrams illustrating examples of functional groups bearing electrical conductivity.

FIG. 6(a) is a diagram explaining a method for synthesizing a silane containing a functional group bearing electrical conductivity. FIG. 6(b) is a diagram illustrating an example of a first polysilsesquioxane having electrical conductivity and synthesized from the silane illustrated in FIG. 6(a), the silane including a functional group bearing electrical conductivity.

FIGS. 7(a) and 7(b) are diagrams illustrating examples of silanes that can be mixed when synthesizing a first polysilsesquioxane having electrical conductivity or a second polysilsesquioxane having a functional group that coordinates with a quantum dot.

FIG. 8(a) is a diagram explaining re-absorption and energy transfer that occur when energy in an excited state of a first polysilsesquioxane having electrical conductivity is lower than energy in an excited state of the quantum dot, and FIG. 8(b) is a diagram for explaining the reason why re-absorption and energy transfer do not occur if the energy in the excited state of the first polysilsesquioxane having electrical conductivity is higher than the energy in the excited state of the quantum dot.

FIG. 9 is a diagram explaining the reason why re-absorption and energy transfer do not occur when the energy in the singlet excited state of the first polysilsesquioxane having electrical conductivity is higher than the energy in the excited state of the quantum dot, and the distance between the first polysilsesquioxane having electrical conductivity and the quantum dot is 1 nm or greater.

FIGS. 10(a) and (b) are tables indicating HOMO levels, LUMO levels, singlet excitation levels, and triplet excitation levels of examples of functional groups bearing electrical conductivity.

FIG. 11 is a table indicating HOMO levels, LUMO levels, singlet excitation levels, and triplet excitation levels of other examples of functional groups bearing electrical conductivity.

FIG. 12 is an image illustrating a schematic configuration of a light-emitting element according to the first embodiment.

FIG. 13(a) is an image illustrating a schematic configuration of a light-emitting element according to a second embodiment, and FIG. 13(b) is an image illustrating a schematic configuration of a nanoparticle provided in the light-emitting element of the second embodiment.

FIG. 14(a) is an image illustrating a schematic configuration of a light-emitting element according to a third embodiment, and FIG. 14(b) is an image illustrating a schematic configuration of a nanoparticle provided in the light-emitting element of the third embodiment.

FIG. 15 is a diagram for explaining a method for synthesizing a first polysilsesquioxane having electrical conductivity in a light-emitting layer provided in the light-emitting element of the third embodiment.

FIG. 16 is a diagram illustrating a schematic configuration of a light-emitting element according to a fourth embodiment.

FIGS. 17(a), (b), and (d) are diagrams illustrating a conventional nanoparticle in which a quantum dot is sealed with a chemically and thermally stable material, and FIG. 17(c) is a diagram illustrating a conventional film in which the quantum dots are sealed with a chemically and thermally stable material.

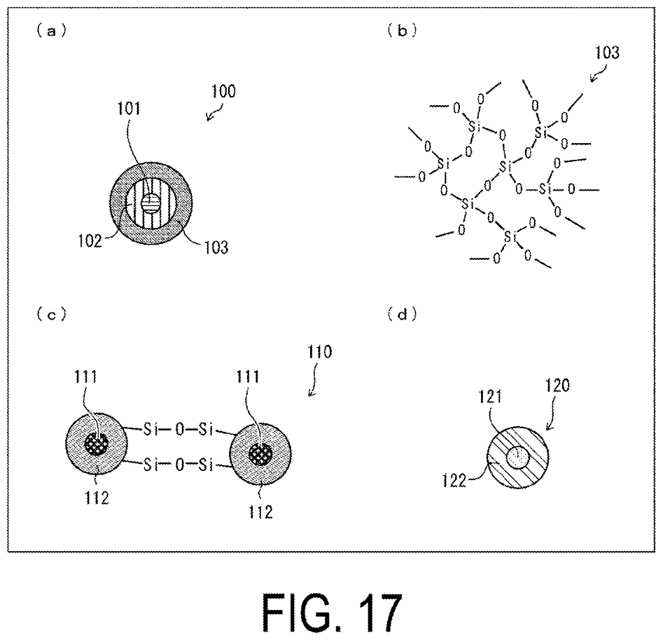

### DESCRIPTION OF EMBODIMENTS

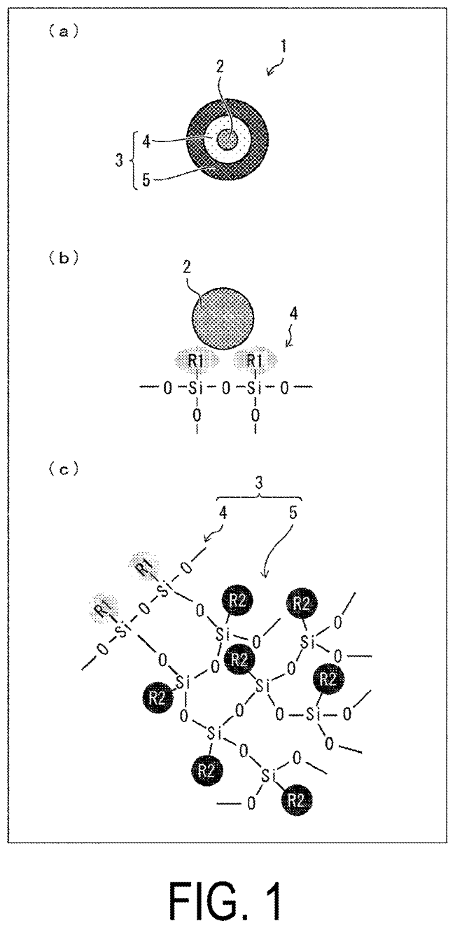

Embodiments of the present invention are described as follows on the basis of FIG. 1 to FIG. 16. Hereinafter, for convenience of description, components having the same functions as those described in a specific embodiment are denoted by the same reference numerals, and descriptions thereof may be omitted.

### First Embodiment

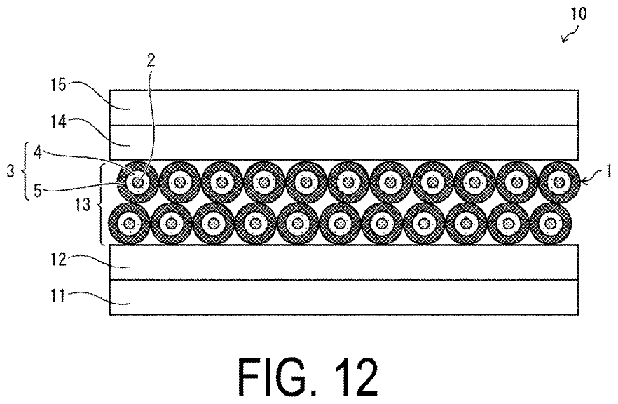

FIG. 12 is an image illustrating a schematic configuration of a light-emitting element 10 according a first embodiment.

As illustrated in FIG. 12, the light-emitting element 10 includes a first electrode 11, a second electrode 15, and a light-emitting layer 13 that contains nanoparticles 1 and is provided between the first electrode 11 and the second electrode 15. The light-emitting element 10 is also provided with a first carrier transport layer 12 between the first electrode 11 and the light-emitting layer 13, and a second carrier transport layer 14 between the light-emitting layer 13 and the second electrode 15.

Note that, for example, according to the resolution of a display device, a plurality of the light-emitting elements 10 are formed on an active matrix substrate provided with a plurality of thin-film transistor elements (TFT elements), which are not illustrated, and the first electrode 11 provided in each light-emitting element 10 is electrically connected to a drain electrode of the thin-film transistor element.

The present embodiment is explained using an example of a case in which the first electrode 11, the first carrier transport layer 12, the light-emitting layer 13, the second carrier transport layer 14, and the second electrode 15 are formed in this order on the active matrix substrate, but the present invention is not limited thereto, and the second electrode 15, the second carrier transport layer 14, the light-emitting layer 13, the first carrier transport layer 12, and the first electrode 11 may be formed in this order on the active matrix substrate.

The light-emitting layer 13 in the light-emitting element 10 emits light of a first wavelength range. Further, in addition to the light-emitting element 10 that emits light of the first wavelength range on the active matrix substrate, at least a light-emitting element provided with a light-emitting layer that emits light of a second wavelength range having a center wavelength that differs from that of the first wavelength range, and a light-emitting element provided with a light-emitting layer that emits light of a third wavelength range having a center wavelength that differs from that of the first wavelength range and the second wavelength range are formed on the active matrix substrate. Four or more types of such light-emitting elements that emit light of mutually different wavelength ranges may be formed.

In a case of light-emitting layers having quantum dots, in order to configure such that the center wavelengths of emitted light are mutually different, the light-emitting layers may be configured with quantum dots having mutually different particle diameters between the light-emitting layers, or may be configured to each use quantum dots of a mutually different type.

Only a case in which quantum dots 2 and a first polysilsesquioxane 3 having electrical conductivity are contained in the light-emitting layer 13 that emits light in the first wavelength range is described below. However, a light-emitting layer of a light-emitting element that emits light in the second wavelength range and a light-emitting layer of a light-emitting element that emits light in the third wavelength range may likewise include quantum dots and a first polysilsesquioxane 3 having electrical conductivity.

When the light-emitting element 10 is a top-emitting type, a metal material having high reflectivity of visible light, such as Al, Cu, Au, and Ag, may be used as the first electrode 11. Also, for example, indium tin oxide (ITO) and an alloy containing Ag may be layered and used as the first electrode 11 as long as the reflectivity of visible light is high. As the second electrode 15, a material having high transmittance of visible light (a transparent conductive film material), such as indium tin oxide (ITO), indium zinc oxide (IZO), ZnO, aluminum-doped zinc oxide (AZO), and boron-doped zinc oxide (BZO), may be used.

On the other hand, when the light-emitting element 10 is a bottom-emitting type, a material having a high transmittance of visible light (a transparent conductive film material) can be used as the first electrode 11, and as the second electrode 15, a metal material having high reflectivity of visible light or, for example, indium tin oxide (ITO) and an alloy containing Ag may be layered and used as long as the reflectivity of visible light is high.

The present embodiment is described using, as an example, a case in which the first electrode 11 is an anode (anode electrode) and the second electrode 15 is a cathode (cathode electrode), and therefore the first carrier transport layer 12 between the first electrode 11 and the light-emitting layer 13 is a hole transport layer, and the second carrier transport layer 14 between the light-emitting layer 13 and the second electrode 15 is an electron transport layer. However, the present invention is not limited thereto. The light-emitting element 10 may be provided with a hole injection layer between the first electrode 11 and the first carrier transport layer 12 serving as a hole transport layer, or may be provided with an electron injection layer between the second carrier transport layer 14, which is an electron transport layer, and the second electrode 15. Further, an electron blocking layer may be provided between the first carrier transport layer 12, which is a hole transport layer, and the light-emitting layer 13, and a hole blocking layer may be provided between the light-emitting layer 13 and the second carrier transport layer 14, which is an electron transport layer.

(a) of FIG. 1 is a diagram illustrating a schematic configuration of a nanoparticle 1 included in the light-emitting layer 13 of the light-emitting element 10. (b) of FIG. 1 is a diagram illustrating a functional group moiety 4 that coordinates to a quantum dot 2 of the first polysilsesquioxane 3 having electrical conductivity, and (c) of FIG. 1 is a diagram illustrating a schematic configuration of the first polysilsesquioxane 3 having electrical conductivity.

As illustrated in (a) of FIG. 1, the nanoparticle 1 includes a quantum dot 2 (also referred to as a phosphor quantum dot) and a first polysilsesquioxane 3 having electrical conductivity. As the specific material of the quantum dots 2, for example, any of CdSe/CdS, CdSe/ZnS, InP/ZnS, ZnSe/ZnS, CIGS/ZnS, AgInS2/GaS, and lead halide perovskite may be used, and the particle diameter of the quantum dot is around 3 to 10 nm. The first polysilsesquioxane 3 having electrical conductivity includes a functional group moiety 4 that coordinates with a quantum dot 2 and a functional group moiety 5 bearing electrical conductivity of the first polysilsesquioxane 3.

As illustrated in (b) of FIG. 1, the functional group moiety 4 that coordinates with a quantum dot 2 in the first polysilsesquioxane 3 having electrical conductivity has a functional group R1 that coordinates with a quantum dot 2.

As illustrated in (c) of FIG. 1, the first polysilsesquioxane 3 having electrical conductivity is a polysilsesquioxane having both a functional group moiety 4, which coordinates with a quantum dot 2 and has a functional group R1 that coordinates with the quantum dot 2, and a functional group moiety 5, which bears electrical conductivity of the first polysilsesquioxane 3 and has a functional group R2 bearing electrical conductivity. As illustrated in (a) of FIG. 1, the first polysilsesquioxane 3 having electrical conductivity is disposed surrounding the quantum dot 2 and protects the quantum dot 2.

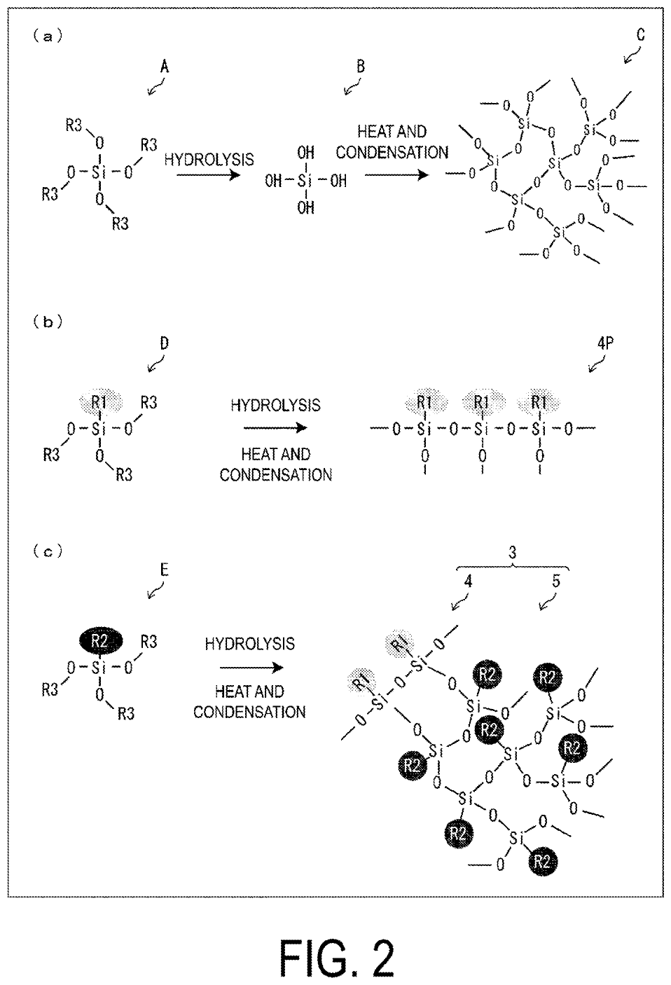

(a) of FIG. 2 is a diagram explaining a method for synthesizing a silica C, (b) of FIG. 2 is a diagram explaining a method for synthesizing a second polysilsesquioxane 4P having a functional group R1 that coordinates with a quantum dot 2, and (c) of FIG. 2 is a diagram explaining a method for synthesizing the first polysilsesquioxane 3 having electrical conductivity.

As illustrated in (a) of FIG. 2, a tetraalkoxy silane A (in the drawing, R3 is an alkyl group such as methyl or ethyl, for example) can be hydrolyzed in the presence of an acid/base catalyst to obtain a silane B having a silanol group, and the silane B having a silanol group can be condensed by heating to produce a silica C having a three-dimensional structure. The silica C is a chemically and thermally stable material, but is also an insulator having a large band gap, and therefore is not preferred as a material to protect the quantum dots 2.

In the present embodiment, as illustrated in (b) of FIG. 2, a trialkoxy silane D having a functional group R1 that coordinates with a quantum dot 2 (in the drawing, R3 is an alkyl group such as methyl or ethyl, for example) is hydrolyzed, heated and condensed in the presence of an acid/base catalyst in a state in which the functional group R1 that coordinates with a quantum dot 2 is coordinated to the surface of the quantum dot 2, that is, in a state in which, of the trialkoxy silane D component, the functional group R1 that coordinates with a quantum dot 2 is facing the quantum dot 2, and a monomolecular film of the second polysilsesquioxane 4P having a three-dimensional structure surrounding the quantum dot 2 can be formed.

Therefore, as illustrated in (c) of FIG. 2, a trialkoxy silane E having a functional group R2 bearing electrical conductivity (R3 in the drawing is an alkyl group such as methyl or ethyl, for example) is added, hydrolysis and heat condensation are carried out in the presence of an acid/base catalyst, and a first polysilsesquioxane 3 having both the functional group moiety 4 that coordinates with a quantum dot 2 and has a functional group R1 that coordinates with the quantum dot 2, and a functional group moiety 5 that is bearing electrical conductivity and has a functional group R2 bearing electrical conductivity can be obtained. Note that the functional group moiety 4 that coordinates with a quantum dot 2 and the functional group moiety 5 bearing electrical conductivity are chemically bonded because the silanol groups of second polysilsesquioxane 4P and the silanol groups of the silane having the functional group R2 bearing electrical conductivity condense.

Note that in the synthesis process of the first polysilsesquioxane 3 having both the functional group moiety 4 that coordinates with the quantum dot 2 and the functional group moiety 5 bearing electrical conductivity, the first polysilsesquioxane 3 can be mainly obtained. However, a second polysilsesquioxane 4P, a trialkoxy silane D (including those for which a portion has formed a silanol group) having a functional group R1 that coordinates with a quantum dot 2, a trialkoxy silane E (including those for which a portion has formed a silanol group) having a functional group R2 bearing electrical conductivity, and the like may also be intermingled.

The term polysilsesquioxane (PSQ) denotes a polymeric product that has a siloxane bond (Si—O—Si) as the main chain, and has a functional group that is directly bonded to a Si atom and is produced from a trialkoxy silane having a functional group directly bonded to a Si atom (silicon element) (may include a tetraalkoxy silane, a dialkoxy silane having a functional group directly bonded to a Si atom, a monoalkoxy silane having a functional group that is directly bonded to a Si atom, and the like).

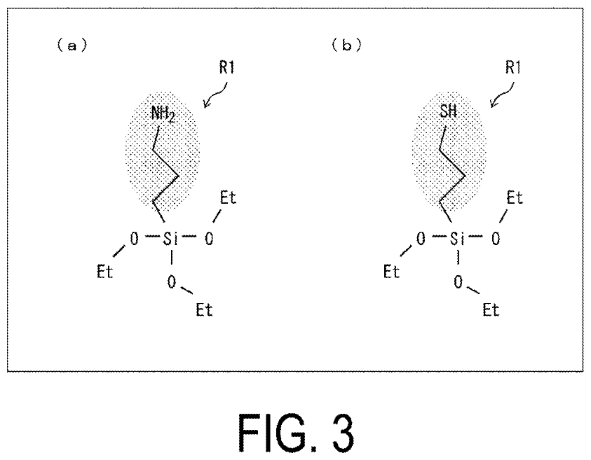

(a) of FIG. 3 is a diagram illustrating an example of a silane including a functional group R1 that coordinates to a quantum dot 2 and has an amino group. (b) of FIG. 3 is a diagram illustrating an example of a silane including a functional group R1 that coordinates to a quantum dot 2 and has a thiol group. As the trialkoxy silane D having the functional group R1 that coordinates to the quantum dot 2 as illustrated in (b) of FIG. 2, 3-aminopropyltriethoxy silane illustrated in (a) of FIGS. 3 and/or 3-(triethoxysilyl) propanethiol illustrated in (b) of FIG. 3 can be used, for example.

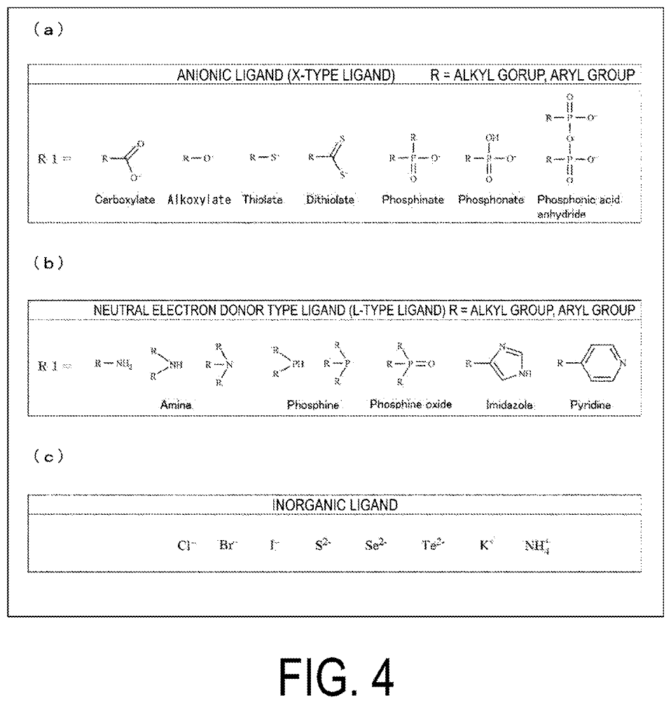

(a), (b), and (c) of FIG. 4 are diagrams illustrating examples of ligands that coordinate with the quantum dots 2.

Amino groups, thiol groups, alkoxy groups, carboxy groups, phosphino groups, phosphino-oxide groups, imidazolium groups, pyridinyl groups, and the like are known as functional groups that coordinate with a semiconductor quantum dot surface of groups II-VI such as CdSe or groups III-V such as InP, which are used as materials for the quantum dots 2 (see Coordination Chemistry Reviews, Vol. 320-321 (2016), pp. 216-237). It is thought that the functional groups R1 that coordinate with the quantum dots 2 are ionized and coordinated with the quantum dots 2.

(a) of FIG. 4 illustrates an example of an anionic ligand that coordinates with the quantum dot 2. As an anionic ligand that coordinates with the quantum dots 2, examples include ligands including at least one selected from carboxylates, alkoxylates, thiolates, dithiolates, phosphylates, phosphonates, and phosphoric anhydrides.

(b) of FIG. 4 illustrates an example of a neutral electron donor type ligand. As a neutral electron donor type ligand that coordinates with the quantum dots 2, examples include ligands including at least one selected from primary to tertiary amines, secondary and tertiary phosphines, phosphinic acids, imidazoles, and pyridines.

(c) of FIG. 4 illustrates an example of an inorganic ligand. As the inorganic ligand, at least one of Cl⁻, Br⁻, I⁻, S²⁻, Se²⁻, Te²⁻, K⁺, and NH₄⁺ can be selected.

Additionally, (a) and (b) of FIG. 4 illustrate silanes or alkyl groups bonded to a silane. Not all ligands coordinating with the quantum dots 2 need be directly or indirectly bonded to a silane, and for example, an inorganic ligand such as those illustrated in (c) of FIG. 4 may be coordinated.

In (a) and (b) of FIG. 3 and (a) and (b) of FIG. 4, the ligand that coordinates with a quantum dot 2 is incorporated by the Si atom through an alkyl group (R═(CH₂)n, where n is a natural number of 1 or greater), but is not limited thereto, and for example, the ligand may be incorporated by the Si atom through an aryl group and may be incorporated directly by the Si atom.

Furthermore, the proportion of the functional group that coordinates with the surface of a semiconductor quantum dot, namely the proportion of the functional group such as an amino group, a thiol group, an alkoxy group, a carboxy group, a phosphino group, an phosphino-oxide group, an imidazolium group, a pyridinyl group, a quaternary ammonium cation, a thiolate anion, and an alkoxide anion, a carboxylate anion, a phosphinolate cation, and an oxidized phosphinolate cation is, in terms of a molar ratio with respect to Si atoms, preferably from 0.1% to 50%, and more preferably from 0.1% to 20%. This is because when the proportion exceeds 50%, there is a concern that excess ligands that do not coordinate with the quantum dots may be present.

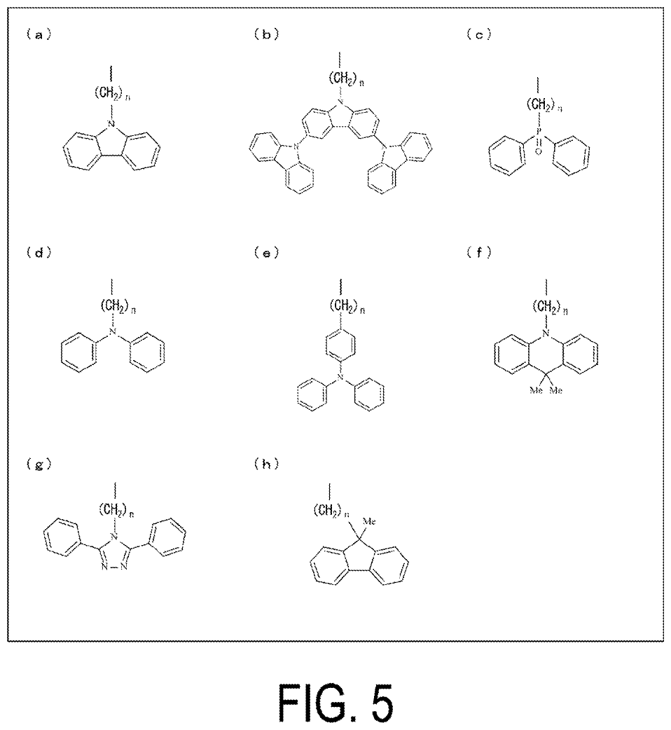

(a) to (h) of FIG. 5 are diagrams illustrating examples of functional groups R2 bearing electrical conductivity. At least one type of functional group R2 is selected from the functional groups illustrated in (a) to (h) of FIG. 5.

Polysilsesquioxane (PSQ) having a functional group including a carbazole skeleton illustrated in (a) of FIG. 5 is known to have electrical conductivity (refer to Chem. Eur. J. 2014, vol. 20, pp. 12773-12776). In addition, examples of polysilsesquioxanes having electrical conductivity include polysilsesquioxanes (PSQ) having a functional group including a n-conjugated (pi-conjugated) type skeleton such as a functional group including the carbazole skeleton illustrated in (b) of FIG. 5, a functional group having the biphenyl phosphine oxide skeleton illustrated in (c) of FIG. 5, a functional group including a diphenylamine skeleton (biphenyl amine skeleton) illustrated in (d) of FIG. 5, a functional group including the triphenylamine skeleton illustrated in (e) of FIG. 5, a functional group including the dimethylacridine skeleton illustrated in (f) of FIG. 5, a functional group including the biphenyl triazole skeleton illustrated in (g) of FIG. 5, the functional group including a fluorene skeleton illustrated in (h) of FIG. 5, a functional group (not illustrated) including an anthracene skeleton, a functional group (not illustrated) including a phenoxazine skeleton, a functional group (not illustrated) including a phenothiazine skeleton, a functional group (not illustrated) including a biphenyl skeleton, a functional group (not illustrated) including an imidazole skeleton, a functional group (not illustrated) including a 1,2,4-triazole skeleton, a functional group (not illustrated) including a 1,3,4-thiadiazole skeleton, and a functional group (not illustrated) including an oxadiazole skeleton.

Note that in (a) to (h) of FIG. 5, the functional group R2 bearing electrical conductivity is incorporated by the Si atom through an alkyl group (R═(CH₂)n, where n is a natural number of 1 or greater), but the present invention is not limited thereto, and for example, the functional group R2 may be incorporated by the Si atom through an aryl group, or may be directly incorporated by the Si atom.

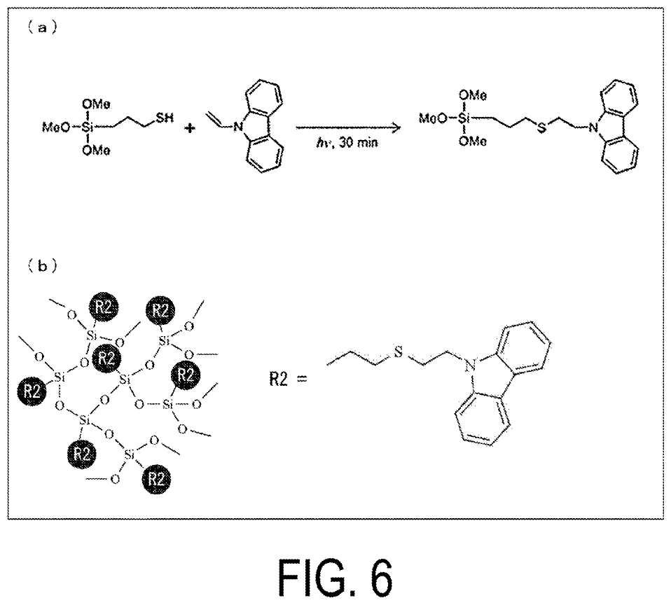

(a) of FIG. 6 is a diagram explaining a method for synthesizing a silane containing the functional group R2 bearing electrical conductivity. FIG. 6(b) is a diagram illustrating an example of a first polysilsesquioxane having electrical conductivity and synthesized from the silane illustrated in (a) of FIG. 6, the silane thereof including the functional group R2 bearing electrical conductivity.

When a trialkoxy silane containing a functional group R2 bearing electrical conductivity is difficult to procure, as illustrated in (a) of FIG. 6, for example, carbazole-ethylthio-propyltrimethoxy silane (CTTMS), which is a trialkoxysilane including a functional group R2 bearing electrical conductivity, can be obtained by reacting 3-mercaptopropyl trimethoxysilane serving as a silane having a thiol group and 9-vinylcarbazole for 30 minutes through only light irradiation. In this manner, a thi ol-ene reaction can be used to synthesize a trialkoxy silane having a desired functional group (refer to Chem. Eur. J. 2014, vol. 20, pp. 12773-12776). Furthermore, such a thiol-ene reaction is effective because the reaction proceeds only by light irradiation and does not produce by-products.

In the present embodiment, the functional group R1 that coordinates with the quantum dot 2 was explained using, as an example, a first polysilsesquioxane 3 having both a functional group moiety 5 bearing electrical conductivity and a functional group moiety 4 that coordinates with the quantum dot 2, the functional group moiety 4 being incorporated using a silane including a functional group R1 that coordinates with a quantum dot 2, as illustrated in (b) of FIG. 2, (a) of FIG. 3 and (b) of FIG. 3. However, the functional group R1 that coordinates with the quantum dot 2 need not be incorporated using a silane including the functional group R1 that coordinates with the quantum dot 2 as illustrated in (b) of FIG. 2, (a) of FIG. 3 and (b) of FIG. 3. The reason for this is that, for example, after the carbazole-ethylthio-propyltrimethoxy silane (CTTMS) that is illustrated in (a) of FIG. 6 and is a trialkoxysilane precursor, is reacted in a solvent such as alcohol with water of an amount equal to or greater than the molar ratio of the alkoxy groups for one hour or longer in the presence of an acid/base catalyst, and is hydrolyzed, a large number of silanol groups (Si—OH groups) are produced. Therefore, when the silanol groups (Si—OH groups) of the CTTMS from which the silanol groups were produced are in a state of being coordinated with the quantum dots 2, and are heated to 60° C. or higher and subjected to dehydration condensation, the first polysilsesquioxane illustrated in (b) of FIG. 6 and having a functional group R2 that is bearing electrical conductivity of the solid is obtained. In this case, a cage-shaped polysilsesquioxane is partially produced, but this is not a problem from a characteristic perspective.

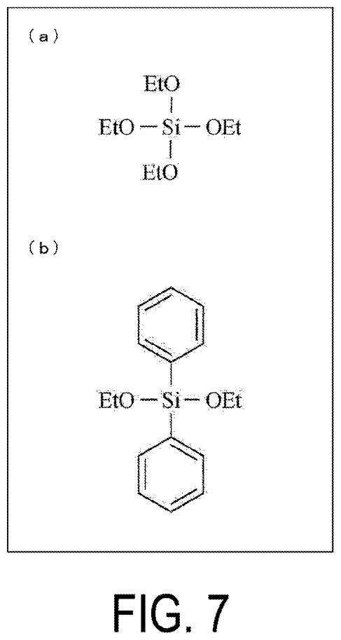

(a) and (b) of FIG. 7 are diagrams illustrating examples of silanes that can be mixed when synthesizing a first polysilsesquioxane having electrical conductivity or a second polysilsesquioxane having a functional group that coordinates with a quantum dot.

In conjunction with the CTTMS that is a trialkoxy silane precursor and is illustrated in (a) of FIG. 6, for example, tetraethoxy silane (TEOS), which is a raw material of silica and is the tetraalkoxy silane illustrated in (a) of FIG. 7, or diethoxydiphenyl silane, which is a raw material of silicone and is a dialkoxy silane having a functional group directly bonded to a Si atom, may be mixed into the precursor.

According to Chem. Eur. J. 2014, vol. 20, pp. 12773-12776, a polysilsesquioxane (PSQ) having a functional group including a carbazole skeleton as illustrated in (a) of FIG. 5 is known to be a semiconductor having an electrical conductivity rate of approximately 10⁵ to 104 [S·cm⁻¹] (a semiconductor has an electrical conductivity rate of from 10⁻⁸ to 10³ [S·cm⁻¹]). In order to obtain luminance that can be observed by the human eye from a light-emitting element provided with a light-emitting layer including quantum dots, a carrier must be injected into the light-emitting layer at a current density of 10⁻² Acm⁻² or greater. For example, when 5 V is applied to a 50 nm semiconductor layer, the electrical conductivity rate required to obtain a current density of 10⁻² Acm⁻² is 10⁻⁸ [S·cm⁻¹], and if the electrical conductivity is equal to a greater than this value, a minimum carrier transport function can be supported.

When an organic amorphous solid such as a polysilsesquioxane has a unit made from a pi-conjugation, the carrier is transported through hopping conduction. An electrical conductivity rate a when hopping conduction occurs in the solid decreases as a distance γ between hopping sites (here, the pi-conjugation unit) increases, and can be described by the following [Expression 1] (refer to Yuki Handotai no Debaisu Bussei, Kodansha, Chihaya ADACHI).

σ∝exp(−2αr) [Expression 1]

Note that α in [Expression 1] is an inverse number of the spread of the wave function of the hopping site. The distance γ between hopping sites can be approximated as being proportional to the inverse number of the cube root of the concentration C of the hopping site, and is expressed by the following [Expression 2].

r∝1/\sqrt{C} [Expression 2]

When Expression 1 and Expression 2 are applied to an example of a polysilsesquioxane having a carbazole, a calculation result like that indicated below is obtained. Assuming that the distance between carbazoles is 5 times the wave function of the carbazole, calculations indicate that when the concentration of carbazole in the polysilsesquioxane becomes 20% of the original concentration, the average distance between carbazoles becomes 1.7 times, the electrical conductivity rate becomes 1/1000, and the electrical conductivity rate decreases to approximately 10⁻⁸ [S·cm⁻¹]. In other words, in the case of a polysilsesquioxane having a carbazole, in order to obtain an electrical conductivity rate of 10⁻⁸ [S·cm¹] or greater, the molar ratio of carbazole units to Si atoms must be 20% or greater. This value varies somewhat depending on the type of pi-conjugation unit and the length of the alkyl chain, but the same trend is exhibited.

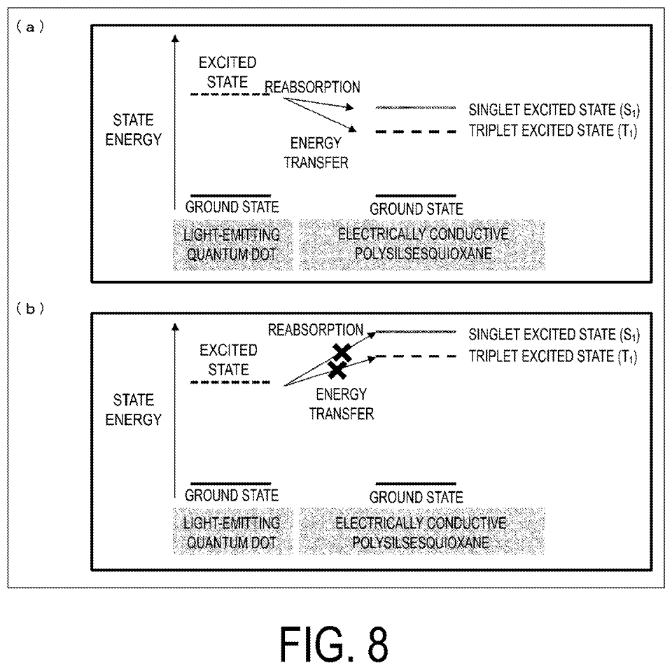

(a) of FIG. 8 is a diagram for explaining re-absorption and energy transfer that occur when energy in an excited state of a first polysilsesquioxane having electrical conductivity (electrically conductive polysilsesquioxane) is lower than an energy in an excited state of the quantum dots (light-emitting quantum dots), and (b) of FIG. 8 is a diagram for explaining the reason why re-absorption and energy transfer do not occur if the energy in the excited state of the first polysilsesquioxane having electrical conductivity (electrically conductive polysilsesquioxane) is higher than the energy in the excited state of the quantum dots (light-emitting quantum dots).

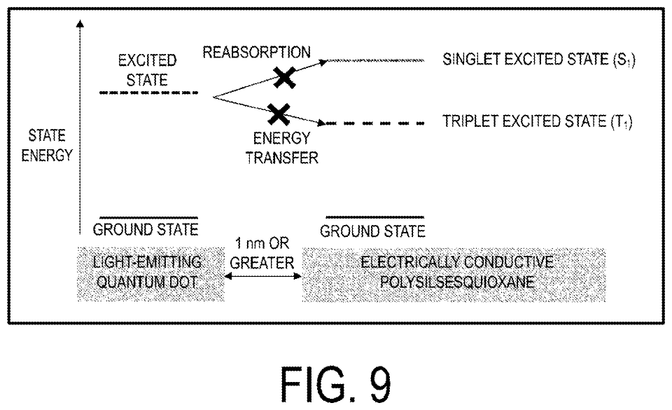

FIG. 9 is a diagram explaining the reason why re-absorption and energy transfer do not occur when the energy in a singlet excited state of the first polysilsesquioxane having electrical conductivity (electrically conductive polysilsesquioxane) is higher than the energy in the excited state of the quantum dots (light-emitting quantum dots), and the distance between the first polysilsesquioxane having electrical conductivity (electrically conductive polysilsesquioxane) and the quantum dots (light-emitting quantum dots) is 1 nm or greater.

The first polysilsesquioxane having electrical conductivity (electrically conductive polysilsesquioxane) necessarily includes a functional group R2 bearing electrical conductivity, but it is preferable to consider the following matters when selecting this functional group R2 bearing electrical conductivity.

In general, when the functional group R2 bearing electrical conductivity is a molecule made from a large pi-conjugation, carrier transport through hopping conduction is easily carried out. On the other hand, when the functional group R2 bearing electrical conductivity has large pi-conjugation, as illustrated in (a) of FIG. 8, the energy of the quantum dots is absorbed, and the external quantum efficiency may be reduced.

Therefore, as illustrated in (b) of FIG. 8, it is preferable to select the functional group R2 bearing electrical conductivity such that the energy in the excited state of the electrically conductive polysilsesquioxane is higher than the energy in the excited state of the light-emitting quantum dots. As illustrated in (b) of FIG. 8, when the level in a singlet excited state (S₁) level of the electrically conductive polysilsesquioxane is higher than the excitation level of the light-emitting quantum dots, the functional group R2 bearing electrical conductivity does not re-absorb the light emitted from the quantum dots. As also illustrated in (b) of FIG. 8, when the level in a triplet excited state (T₁) of the electrically conductive polysilsesquioxane is higher than the excitation level of the light-emitting quantum dots, energy transfer to peripheral pi-conjugation units does not occur through electron exchange.

On the other hand, as illustrated in FIG. 9, if a functional group R2 bearing electrical conductivity is selected such that the level in the singlet excited state (S₁) of the electrically conductive polysilsesquioxane is higher than the excitation level of the light-emitting quantum dots, and the level in the triplet excited state (T₁) of the electrically conductive polysilsesquioxane is lower than the excitation level of the light-emitting quantum dots, the light-emitting quantum dots and the electrically conductive polysilsesquioxane having the functional group R2 bearing electrical conductivity are separated by a distance of 1 nm or greater, and thereby energy transfer to the peripheral pi-conjugation units does not occur through electron exchange.

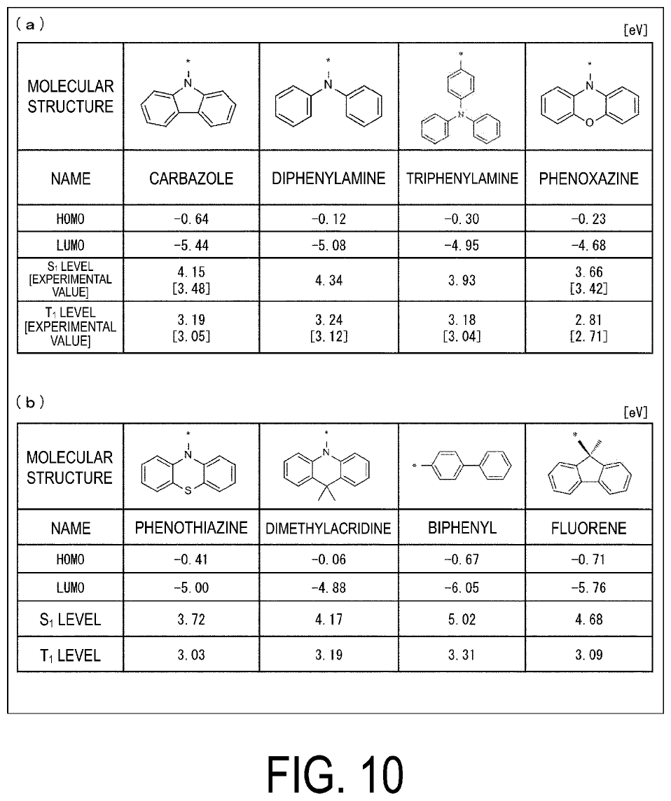

(a) and (b) of FIG. 10 are tables indicating HOMO levels, LUMO levels, singlet excitation levels (S₁ levels), and triplet excitation levels (T₁ levels) of examples of functional groups R2 bearing electrical conductivity.

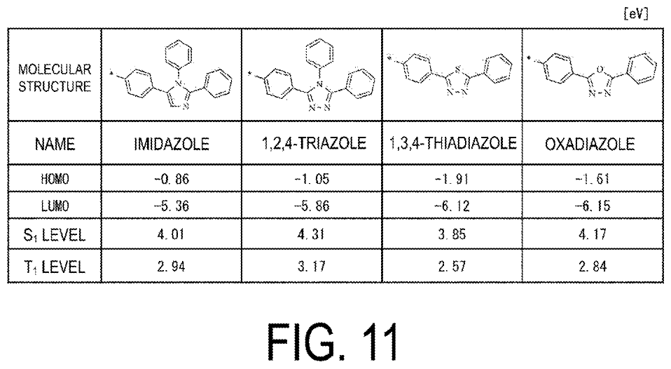

FIG. 11 is a table indicating HOMO levels, LUMO levels, singlet excitation levels (Si), and triplet excitation levels (T₁) of other examples of functional groups R2 bearing electrical conductivity.

Experimental values of the singlet excitation levels (S₁ level) and the triplet excitation levels (T₁ level) in FIG. 10 and FIG. 11 can be determined as follows. The singlet excitation level (S₁ level) of the first polysilsesquioxane having electrical conductivity (polysilsesquioxane having pi-conjugation) or of the functional group R2 having electrical conductivity (pi-conjugation unit) is determined through a UV-Vis spectrum or a fluorescence spectrum, and the triplet excitation level (T₁ level) thereof is determined from a phosphorescence spectrum under anaerobic conditions at an extremely low temperature (77 K or lower).

As indicated in FIGS. 10 and 11, the singlet excitation level (S₁ level) and the triplet excitation level (T₁ level) can be calculated using first principle calculations. The calculated values indicated in FIG. 10 and FIG. 11 are values obtained by implementing structural optimization through the density-functional theory of the Gaussian 09 program package using B3LYP as a functional and 6-31g(d) as a basis function, and calculating the singlet excitation level (S₁ level) and the triplet excitation level (T₁ level).

The * in the molecular structures illustrated in FIG. 10 and FIG. 11 denotes a bondable site and may be bonded directly to a Si atom, or may be bonded to a Si atom through an aryl group or an alkyl group, for example. In other words, the functional group R2 bearing electrical conductivity and illustrated in FIG. 10 and FIG. 11 may include, for example, an aryl group, an alkyl group, or the like. Note that in the first principle calculation here, calculations are implemented with the assumption that * denotes a hydrogen atom. In addition, with regard to each of the functional groups R2 bearing electrical conductivity and illustrated in FIG. 10 and FIG. 11, there is almost no difference between the excitation level of each of the functional groups R2 bearing electrical conductivity and the excitation level of each of the functional groups R2 bearing electrical conductivity in the polysilsesquioxane.

In general, as the energy gap between the highest occupied molecular orbital level (HOMO) and the lowest unoccupied molecular orbital level (LUMO) becomes smaller, the carrier mobility becomes higher. On the other hand, if the energy gap between the HOMO and the LUMO is too narrow, the singlet excitation level (S₁ level) and the triplet excitation level (T₁ level) also become small, and therefore as illustrated in (a) of FIG. 8, the energy of the quantum dots is absorbed, and the external quantum efficiency is reduced.

Therefore, as illustrated in (b) of FIG. 8, it is preferable to select the functional group R2 bearing electrical conductivity such that the energy in the excited state of the electrically conductive polysilsesquioxane is higher than the energy in the excited state of the light-emitting quantum dots. Note that the energy in the excited state of the light-emitting quantum dots is different for each light-emitting quantum dot having a different light-emission wavelength. For example, energy in an excited state of light-emitting quantum dots that emit light in the green wavelength range is higher than energy in an excited state of light-emitting quantum dots that emit light in the red wavelength range, and energy in an excited state of light-emitting quantum dots that emit light in the blue wavelength range is higher than energy in an excited state of light-emitting quantum dots that emit light in the green wavelength range. The triplet excitation level (T₁ level) of the electrically conductive polysilsesquioxane with consideration of the energy in the excited state of the light-emitting quantum dots that emit light in the red wavelength range is preferably 1.7 eV or greater, and more preferably 2.2 eV or greater. In addition, the triplet excitation level (T₁ level) of the electrically conductive polysilsesquioxane with consideration of the energy in the excited state of the light-emitting quantum dots that emit light in the green wavelength range is preferably 2.2 eV or greater, and more preferably 2.7 eV or greater. Further, the triplet excitation level (T₁ level) of the electrically conductive polysilsesquioxane that takes into account the energy in the excited state of the light-emitting quantum dots that emit light in the blue wavelength range is preferably 2.5 eV or greater, and more preferably 3.0 eV or greater.

As illustrated in FIG. 9, when the light-emitting quantum dots and the electrically conductive polysilsesquioxane having the functional group R2 bearing electrical conductivity can be separated by a distance of 1 nm or greater, the singlet excitation level (S₁ level) of the electrically conductive polysilsesquioxane with consideration of the energy in the excited state of the light-emitting quantum dots that emit light in the red wavelength range is preferably 1.7 eV or greater, and more preferably 2.2 eV or greater. In addition, the singlet excitation level (S₁ level) of the electrically conductive polysilsesquioxane with consideration of the energy in the excited state of the light-emitting quantum dots that emit light in the green wavelength range is preferably 2.2 eV or greater, and more preferably 2.7 eV or greater. Further, the singlet excitation level (S₁ level) of the electrically conductive polysilsesquioxane that takes into account the energy in the excited state of the light-emitting quantum dots that emit light in the blue wavelength range is preferably 2.5 eV or greater, and more preferably 3.0 eV or greater.

The triplet excitation level (T₁ level) of each of carbazole, diphenylamine, triphenylamine, phenoxazine, phenothiazine, diemethylacridine, biphenyl, fluorene, imidazole, 1,2,4-triazole, 1,3,4-thiadiazole, and oxadiazole, which are examples illustrated in FIG. 10 and FIG. 11 of the functional group R2 bearing electrical conductivity, is 2.5 eV or greater. Furthermore, the singlet excitation level (S₁ level) is higher than the triplet excitation level (T₁ level).

Also, with each of each of carbazole, diphenylamine, triphenylamine, phenoxazine, phenothiazine, diemethylacridine, biphenyl, fluorene, imidazole, 1,2,4-triazole, 1,3,4-thiadiazole, and oxadiazole, which are the examples illustrated in FIG. 10 and FIG. 11 of the functional group R2 bearing electrical conductivity, the energy gap between the HOMO level and the LUMO (lowest unoccupied molecular orbital level) is smaller than 6.0 eV, and therefore the carrier mobility is high.

From the above, the functional group R2 bearing electrical conductivity is preferably a functional group containing at least one skeleton selected from among a carbazole skeleton, a diphenylamine skeleton, a triphenyl amine skeleton, a phenoxazine skeleton, a phenothiazine skeleton, a diemethylacridine skeleton, a biphenyl skeleton, a fluorene skeleton, an imidazole skeleton, a 1,2,4-triazole skeleton, a 1,3,4-thiadiazole skeleton, and an oxadiazole skeleton.

The functional group R2 bearing electrical conductivity is a functional group represented by a structural formula of any of the following Chemical Formula 1, Chemical Formula 2, and Chemical Formula 3 below. In Chemical Formula 1, Chemical Formula 2, and Chemical Formula 3 below, * denotes an Si atom of the main chain that includes a siloxane bond of the first polysilsesquioxane having electrical conductivity, or a moiety bonded with a side chain from an Si atom of the main chain, X in Chemical Formula 1 and Chemical Formula 2 below denotes a nitrogen atom, a carbon atom, an oxygen atom, or a sulfur atom, or denotes an absence of an atom, Y in Chemical Formula 3 below denotes a nitrogen atom, a carbon atom, an oxygen atom, or a sulfur atom, and Z in Chemical Formula 3 below denotes a hydrogen atom, an aryl group, or an alkyl group.

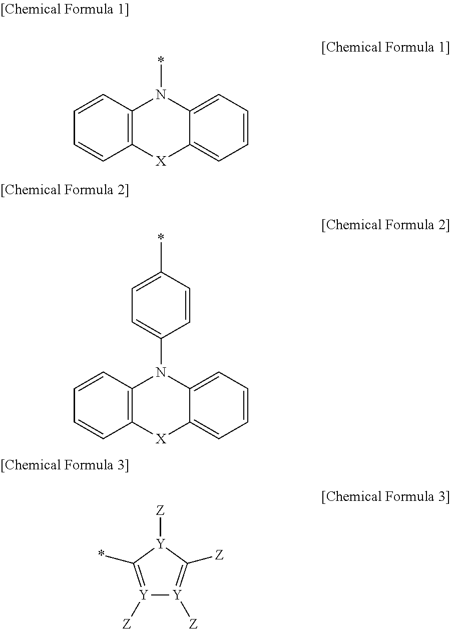

Furthermore, X in Chemical Formula 1 and Chemical Formula 2 denotes a nitrogen atom, a carbon atom, an oxygen atom, or a sulfur atom, and a hydrogen atom, an aryl group, or an alkyl group is bonded to X in Chemical Formula 1 and Chemical Formula 2.

Moreover, from the perspective of using a functional group R2 bearing electrical conductivity and in which the singlet excitation level (S₁ level) and the triplet excitation level (T₁ level) are higher, it is preferable to use a functional group that includes at least one skeleton selected from a carbazole skeleton, an acridine skeleton, a biphenyl skeleton, a diphenylamine skeleton, and a triphenyl amine skeleton, which exhibit a calculated triplet excitation level (T₁ level) of 3.18 eV or greater.

In order to obtain a sufficient carrier transport layer, the proportion of the functional group R2 bearing electrical conductivity is preferably, in terms of a molar ratio with respect to the Si atoms, 20% or greater, and more preferably 80% or greater. In addition, when the functional group R2 bearing electrical conductivity is bonded to three of the four atomic bonds of the Si atom, the functional group R2 becomes an end group, and therefore the proportion of the functional groups R2 bearing electrical conductivity is preferably 200% or less in terms of a molar ratio with respect to the Si atoms.

Note that in the present embodiment, as illustrated in FIG. 9, when the distance between the first polysilsesquioxane 3 having electrical conductivity (electrically conductive polysilsesquioxane) and the quantum dots 2 (light-emitting quantum dots) needs to be 1 nm or greater, the functional group moiety 4 coordinated with the quantum dots of the first polysilsesquioxane 3 may be formed with a thickness of 1 nm or greater.

As described above, according to the present embodiment, a light-emitting element 10 that is highly durable and can emit light through the injection of electrons and positive holes at a relatively low voltage can be realized.

### Second Embodiment

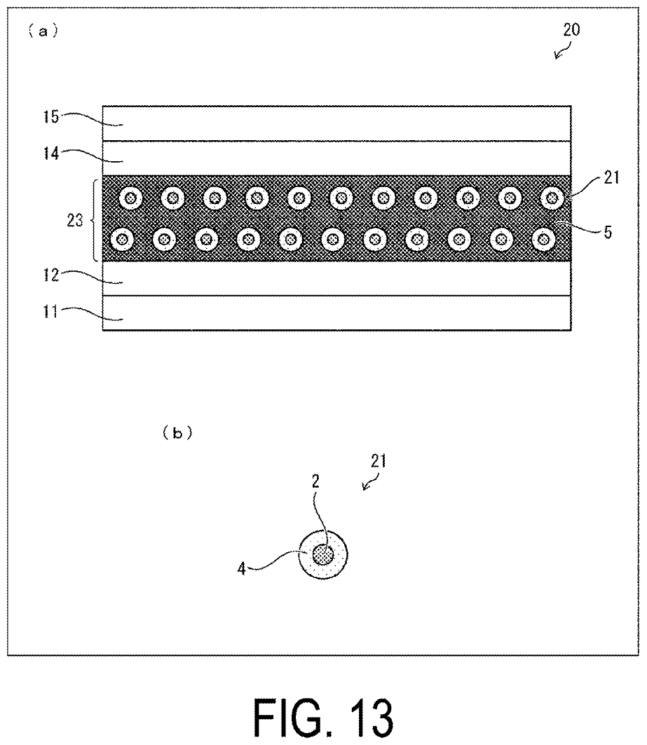

Next, a second embodiment of the present invention will be described on the basis of FIG. 13. A light-emitting element 20 of the present embodiment differs from that of the first embodiment in that a light-emitting layer 23 is formed in a film shape (thin film). All other details are as described with regard to the first embodiment. For convenience of description, members having the same functions as those of the members illustrated in the diagrams in the first embodiment are denoted by the same reference numerals, and descriptions thereof will be omitted.

(a) of FIG. 13 is an image illustrating a schematic configuration of the light-emitting element 20 according to the second embodiment, and (b) of FIG. 13 is an image illustrating a schematic configuration of nanoparticles 21 provided in the light-emitting element 20 of the second embodiment.

As illustrated in (b) of FIG. 13, first, a trialkoxy silane D (see (b) of FIG. 2) having a functional group R1 that coordinates with a quantum dot 2 is hydrolyzed, heated and condensed in the presence of an acid/base catalyst in a state in which a functional group R1 that coordinates with a quantum dot 2 is coordinated to the surface of the quantum dot 2, that is, in a state in which the functional group R1 that coordinates to a quantum dot 2 of the trialkoxy silane D component is facing the quantum dot 2, and a nanoparticle 21 is formed.

Also, as illustrated in (a) of FIG. 13, the nanoparticles 21 and a trialkoxy silane E (refer to (c) of FIG. 2) having a functional group R2 bearing electrical conductivity are added, and hydrolyzed and subjected to heat and condensation in the presence of an acid/base catalyst, and a film-shaped (thin film) light-emitting layer 23 that contains a first polysilsesquioxane having both a functional group moiety 4, which coordinates with a quantum dot 2 and has a functional group R1 that coordinates with the quantum dot 2, and a functional group moiety 5, which bears electrical conductivity and has a functional group R2 bearing the electrical conductivity, can be obtained. That is, the light-emitting layer 23 is a film (thin film) of an electrically conductive polysilsesquioxane in which the quantum dots 2 are intermingled. Note that the functional group moiety 4 that coordinates with the quantum dots 2 of the electrically conductive polysilsesquioxane and the functional group moiety 5 bearing electrical conductivity of the electrically conductive polysilsesquioxane are chemically bonded.

As described above, according to the present embodiment, the light-emitting element 20 provided with the light-emitting layer 23, which is formed in a film shape (thin film), is highly durable, and can emit light through injection of electrons and positive holes at a relatively low voltage, can be realized.

### Third Embodiment

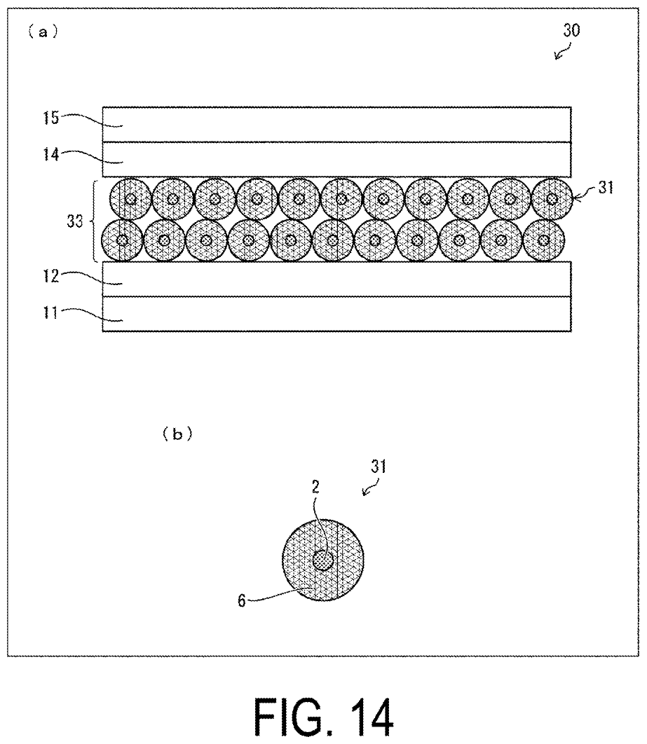

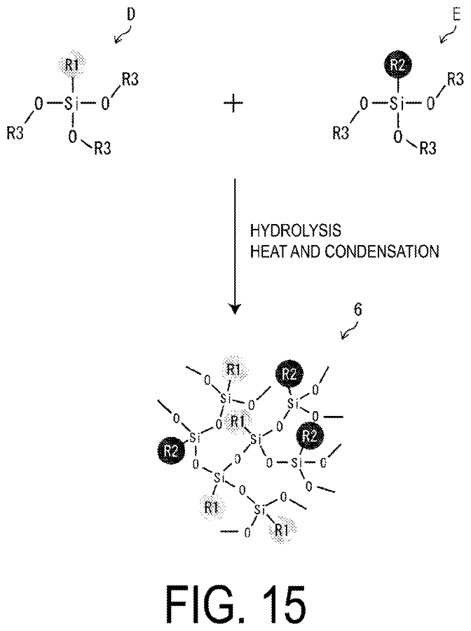

Next, a third embodiment of the present invention will be described below with reference to FIG. 14 and FIG. 15. A light-emitting element 30 of the present embodiment differs from those of the first and second embodiments in that nanoparticles 31 included in a light-emitting layer 33 use a first polysilsesquioxane 6 having electrical conductivity in which a functional group moiety coordinating with quantum dots and a functional group moiety bearing electrical conductivity are intermingled. All other details are as described in the first and second embodiments. For the sake of the description, members having the same functions as the members illustrated in the diagrams in the first and second embodiments are denoted by the same reference numerals, and descriptions thereof will be omitted.

(a) of FIG. 14 is an image illustrating a schematic configuration of the light-emitting element 30 according to the third embodiment, and (b) of FIG. 14 is an image illustrating a schematic configuration of the nanoparticles 31 provided in the light-emitting element 30 of the third embodiment.

FIG. 15 is a diagram for explaining a method for synthesizing the first polysilsesquioxane 6 having electrical conductivity in the light-emitting layer 33 provided in the light-emitting element 30 of the third embodiment.

As illustrated in FIG. 15, quantum dots 2, a trialkoxy silane D having functional groups R1 that coordinate with the quantum dots 2, and a trialkoxy silane E having functional groups R2 bearing electrical conductivity are added, and are hydrolyzed and subjected to heat and condensation in the presence of an acid/base catalyst, and thereby the nanoparticles 31 illustrated in (b) of FIG. 14 can be obtained with a structure in which the first polysilsesquioxane 6 having electrical conductivity surrounds the quantum dot 2, the first polysilsesquioxane 6 having intermingled therein a functional group moiety that coordinates with a quantum dot and a functional group moiety bearing electrical conductivity.

The first polysilsesquioxane 6 surrounding each quantum dot 2 can be formed in one stage despite having both a functional group R1 moiety that coordinates with the quantum dots 2 and a functional group R2 moiety bearing electrical conductivity.

As described above, according to the present embodiment, the light-emitting element 30 provided with the light-emitting layer 33 containing the first polysilsesquioxane 6 that can be formed in one stage can be realized.

### Fourth Embodiment

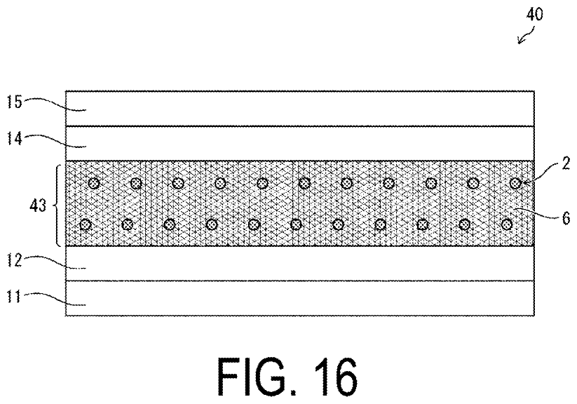

Next, a fourth embodiment of the present invention will be described on the basis of FIG. 16. A light-emitting element 40 of the present embodiment differs from that of the second embodiment in that a light-emitting layer 43 includes the first polysilsesquioxane 6 that can be formed in one stage, and is formed in a film shape (thin film). All other details are as described in the second embodiment. For convenience of description, members having the same functions as those illustrated in the drawings of the second embodiment are denoted by the same reference signs, and the description thereof will be omitted.

FIG. 16 is a diagram illustrating a schematic configuration of the light-emitting element 40 according to the fourth embodiment.

Quantum dots 2, the trialkoxy silane D having functional groups R1 that coordinate with the quantum dots 2 (refer to FIG. 15), and the trialkoxy silane E having functional groups R2 bearing electrical conductivity (refer to FIG. 15) are added, and are hydrolyzed and subjected to heat and condensation in the presence of an acid/base catalyst, and thereby a film-shaped (thin film) light-emitting layer 43 containing the first polysilsesquioxane 6 having electrical conductivity can be obtained, the first polysilsesquioxane 6 having intermingled therein a functional group moiety that coordinates with a quantum dot and a functional group moiety bearing electrical conductivity. That is, the light-emitting layer 43 is a film (thin film) of an electrically conductive polysilsesquioxane in which the quantum dots 2 are intermingled.

As described above, according to the present embodiment, the light-emitting element 40 provided with the light-emitting layer 43 formed in a film shape (thin film) and containing the first polysilsesquioxane 6 that can be formed in one stage can be realized.

### Supplement

### First Aspect

A light-emitting element including:

a first electrode;

a second electrode; and a light-emitting layer provided between the first electrode and the second electrode,

wherein the light-emitting layer includes quantum dots and a first polysilsesquioxane having electrical conductivity.

### Second Aspect

The light-emitting element according to the first aspect,

wherein the first polysilsesquioxane having electrical conductivity includes: a main chain including a siloxane bond; and

a first functional group including a π-conjugated skeleton bonded to the main chain.

### Third Aspect

The light-emitting element according to the second aspect,

wherein the first functional group is a functional group represented by a structural formula of any of Chemical Formula 1, Chemical Formula 2, or Chemical Formula 3 below,

in Chemical Formula 1, Chemical Formula 2, and Chemical Formula 3 below, * denotes an Si atom of the main chain, or a moiety bonded with a side chain from an Si atom of the main chain,

X in Chemical Formula 1 and Chemical Formula 2 below denotes a nitrogen atom, a carbon atom, an oxygen atom, or a sulfur atom, or denotes an absence of an atom,

Y in Chemical Formula 3 below denotes a nitrogen atom, a carbon atom, an oxygen atom, or a sulfur atom, and

Z in Chemical Formula 3 below denotes a hydrogen atom, an aryl group, or an alkyl group.

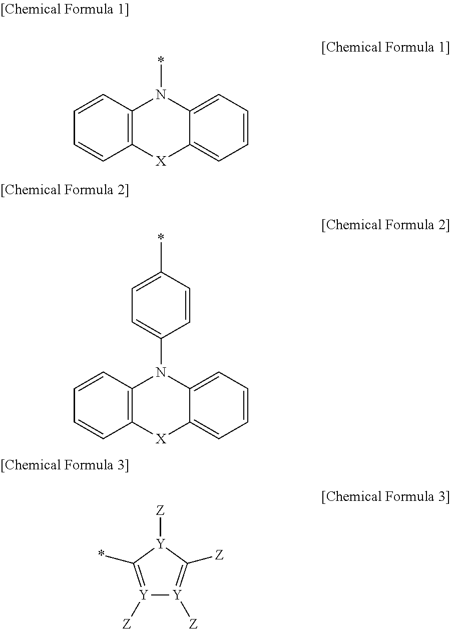

### Fourth Aspect

The light-emitting element according to the third aspect,

wherein X in Chemical Formula 1 and Chemical Formula 2 is a nitrogen atom, a carbon atom, an oxygen atom, or a sulfur atom, and

a hydrogen atom, an aryl group, or an alkyl group is bonded to X in Chemical Formula 1 and Chemical Formula 2.

### Fifth Aspect

The light-emitting element according to the second aspect,

wherein the first functional group is a functional group containing at least one skeleton selected from among a carbazole skeleton, an acridine skeleton, a biphenyl skeleton, a diphenyl amine skeleton, and a triphenyl amine skeleton.

### Sixth Aspect

The light-emitting element according to the second aspect,

wherein the first functional group is a functional group containing at least one skeleton selected from among a carbazole skeleton, a diphenyl amine skeleton, a triphenyl amine skeleton, a phenoxazine skeleton, a phenothiazine skeleton, a diemethylacridine skeleton, a biphenyl skeleton, a fluorene skeleton, an imidazole skeleton, a 1,2,4-triazole skeleton, a 1,3,4-thiadiazole skeleton, and an oxadiazole skeleton.

### Seventh Aspect

The light-emitting element according to any one of the second to sixth aspects,

wherein a molar ratio of the first functional group with respect to Si atoms contained in the first polysilsesquioxane having electrical conductivity is 20% or greater.

### Eighth Aspect

The light-emitting element according to any one of the first to seventh aspects,

wherein the first polysilsesquioxane having electrical conductivity further includes:

a main chain including a siloxane bond; and

a second functional group that coordinates with the quantum dot and is bonded to an Si atom of the main chain.

### Ninth Aspect

The light-emitting element according to any one of the first to eighth aspects, wherein the light-emitting layer further includes a silane containing a second functional group that coordinates with the quantum dot.

### Tenth Aspect

The light-emitting element according to any one of the first to ninth aspects,

wherein the light-emitting layer further includes a second polysilsesquioxane containing:

a main chain including a siloxane bond; and

a second functional group that coordinates with the quantum dot and is bonded to an Si atom of the main chain.

### Eleventh Aspect

The light-emitting element according to any one of the eighth to tenth aspects,

wherein the second functional group is a functional group including at least one type selected from an amino group, a thiol group, an alkoxy group, a carboxy group, a phosphino group, an phosphino-oxide group, an imidazolium group, a pyridinyl group, a quaternary ammonium cation, a thiolate anion, an alkoxide anion, a carboxylate anion, a phosphinolate cation, and an oxidized phosphinolate cation.

### Twelfth Aspect

The light-emitting element according to any one of the eighth to eleventh aspects,

wherein a molar ratio of the second functional group with respect to Si atoms contained in the first polysilsesquioxane having electrical conductivity is from 0.1% to 50%.

### Thirteenth Aspect

The light-emitting element according to any one of the first to twelfth aspects,

wherein the first polysilsesquioxane having electrical conductivity has an electrical conductivity rate of from 10⁻⁸ [S·cm] to 10²[S·cm¹].

### Fourteenth Aspect

The light-emitting element according to the second aspect,

wherein an energy level of a singlet excited state of the first functional group is higher than an energy level of an excited state of the quantum dots.

### Fifteenth Aspect

The light-emitting element according to the second or fourteenth aspect,

wherein an energy level of a triplet excited state of the first functional group is at least 0.5 eV higher than an energy level of an excited state of the quantum dots.

### Sixteenth Aspect

The light-emitting element according to the second or fourteenth aspect,

wherein the quantum dot and the first functional group are separated by 1 nm or greater.

### Seventeenth Aspect

The light-emitting element according to any one of the second, fourteenth, fifteenth, and sixteenth aspects,

wherein a band gap of HOMO-LUMO of the first functional group is smaller than 6.0 eV.

### Additional Items

The present invention is not limited to each of the embodiments described above, and various modifications may be made within the scope of the claims. Embodiments obtained by appropriately combining technical approaches disclosed in each of the different embodiments also fall within the technical scope of the present invention. Furthermore, novel technical features can be formed by combining the technical approaches disclosed in each of the embodiments.

### INDUSTRIAL APPLICABILITY

The present invention can be used in a light-emitting element.

### REFERENCE SIGNS LIST

1, 21, 31 Nanoparticle
2 Quantum dot
3 First polysilsesquioxane having electrical conductivity
4 Functional group moiety that coordinates with quantum dots of the first polysilsesquioxane
4P Second polysilsesquioxane
5 Functional group moiety bearing electrical conductivity of the first polysilsesquioxane
6 First polysilsesquioxane having electrical conductivity
10, 20, 30, 40 Light-emitting element
11 First electrode
12 First carrier transport layer
13, 23, 33, 43 Light-emitting layer
14 Second carrier transport layer
15 Second electrode
D Silane containing a functional group that coordinates with a quantum dot
E Silane containing a functional group bearing electrical conductivity
R1 Functional group (second functional group) that coordinates with a quantum dot
R2 Functional group (first functional group) bearing electrical conductivity

1. A light-emitting element comprising:
a first electrode;
a second electrode; and
a light-emitting layer provided between the first electrode and the second electrode,
wherein the light-emitting layer comprises quantum dots and a first polysilsesquioxane having electrical conductivity.

2. The light-emitting element according to claim 1,
wherein the first polysilsesquioxane having electrical conductivity comprises
a main chain including a siloxane bond, and
a first functional group including a π-conjugated skeleton bonded to the main chain.

3. The light-emitting element according to claim 2,
wherein the first functional group is a functional group represented by a structural formula of any of Chemical Formula 1, Chemical Formula 2, or Chemical Formula 3 below,
in Chemical Formula 1, Chemical Formula 2, and Chemical Formula 3 below, * denotes an Si atom of the main chain, or a moiety bonded with a side chain from an Si atom of the main chain,
X in Chemical Formula 1 and Chemical Formula 2 below denotes a nitrogen atom, a carbon atom, an oxygen atom, or a sulfur atom, or denotes an absence of an atom,
Y in Chemical Formula 3 below denotes a nitrogen atom, a carbon atom, an oxygen atom, or a sulfur atom, and
Z in Chemical Formula 3 below denotes a hydrogen atom, an aryl group, or an alkyl group.

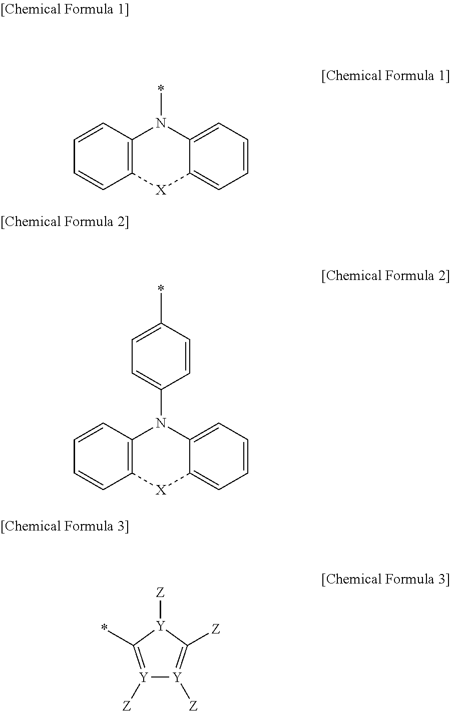

4. The light-emitting element according to claim 3,
wherein X in Chemical Formula 1 and Chemical Formula 2 is a nitrogen atom, a carbon atom, an oxygen atom, or a sulfur atom, and
a hydrogen atom, an aryl group, or an alkyl group is bonded to X in Chemical Formula 1 and Chemical Formula 2.

5. The light-emitting element according to claim 2,
wherein the first functional group is a functional group containing at least one skeleton selected from among a carbazole skeleton, an acridine skeleton, a biphenyl skeleton, a diphenyl amine skeleton, and a triphenyl amine skeleton.

6. The light-emitting element according to claim 2,
wherein the first functional group is a functional group containing at least one skeleton selected from among a carbazole skeleton, a diphenyl amine skeleton, a triphenyl amine skeleton, a phenoxazine skeleton, a phenothiazine skeleton, a diemethylacridine skeleton, a biphenyl skeleton, a fluorene skeleton, an imidazole skeleton, a 1,2,4-triazole skeleton, a 1,3,4-thiadiazole skeleton, and an oxadiazole skeleton.

7. The light-emitting element according to claim 2,
wherein a molar ratio of the first functional group with respect to Si atoms contained in the first polysilsesquioxane having electrical conductivity is 20% or greater.

8. The light-emitting element according to claim 1,
wherein the first polysilsesquioxane having electrical conductivity further comprises
a main chain including a siloxane bond, and
a second functional group coordinating with the quantum dot and bonded to an Si atom of the main chain.

9. The light-emitting element according to claim 1,
wherein the light-emitting layer further comprises a silane containing a second functional group coordinating with the quantum dot.

10. The light-emitting element according to claim 1,
wherein the light-emitting layer further includes a second polysilsesquioxane comprising:
a main chain including a siloxane bond; and
a second functional group coordinating with the quantum dot and bonded to a Si atom of the main chain.

11. The light-emitting element according to claim 8,
wherein the second functional group is a functional group including at least one type selected from an amino group, a thiol group, an alkoxy group, a carboxy group, a phosphino group, an phosphino-oxide group, an imidazolium group, a pyridinyl group, a quaternary ammonium cation, a thiolate anion, an alkoxide anion, a carboxylate anion, a phosphinolate cation, and an oxidized phosphinolate cation.

12. The light-emitting element according to claim 8,
wherein a molar ratio of the second functional group with respect to Si atoms contained in the first polysilsesquioxane having electrical conductivity is from 0.1% to 50%.

13. The light-emitting element according to claim 1,
wherein the first polysilsesquioxane having electrical conductivity has an electrical conductivity rate of from 10⁻⁸ [S·cm−1] to 10²[S·cm−1].

14. The light-emitting element according to claim 2,
wherein an energy level of a singlet excited state of the first functional group is higher than an energy level of an excited state of the quantum dots.

15. The light-emitting element according to claim 2,
wherein an energy level of a triplet excited state of the first functional group is at least 0.5 eV higher than an energy level of an excited state of the quantum dots.

16. The light-emitting element according to claim 2,
wherein the quantum dot and the first functional group are separated by 1 nm or greater.

17. The light-emitting element according to claim 2,
wherein a band gap of HOMO-LUMO of the first functional group is smaller than 6.0 eV.
